(19) United States
(12) Patent Application Publication
(10) Pub. No.: US 2006/0022241 A1
(43) Pub. Date: Feb. 2, 2006

(54) Semiconductor memory device having capacitor using dielectric film, and method of fabricating the same

(76) Inventors: Yoshiro Shimojo, Yokohama-shi (JP); Yoshinori Kumura, Yokohama-shi (JP); Iwao Kunishima, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/958,468

(22) Filed: Oct. 6, 2004

(30) Foreign Application Priority Data
Jul. 29, 2004 (JP) 2004-221927

(51) Int. Cl. H01L 29/94; H01L 21/8242

(52) U.S. Cl. 257/296; 438/239

(57) ABSTRACT

A transistor is formed in a surface region of a semiconductor substrate. A capacitor is formed above the transistor, and has a first electrode, a second electrode, and a dielectric film formed between the first and second electrodes. A first contact is formed on a side surface portion of the capacitor so as to be close to at least a portion of the capacitor, and connected to one of source/drain regions. A side insulating film is formed, in contact with at least the capacitor, on the sidewalls of the first contact.

### CROSS-REFERENCE TO RELATED APPLICATIONS

This application is based upon and claims the benefit of priority from prior Japanese Patent Application No. 2004-221927, filed Jul. 29, 2004, the entire contents of which are incorporated herein by reference.

### BACKGROUND OF THE INVENTION

1. Field of the Invention

The present invention relates to a semiconductor memory device having a capacitor using a dielectric film, and a method of fabricating the same.

2. Description of the Related Art

Semiconductor memory devices using a dielectric film or ferroelectric film as an inter-electrode insulating film of a capacitor for holding data have been developed (e.g., Jpn. Pat. Appln. KOKAI Publication Nos. 10-275897 and 2000-036568).

Also, a chain type semiconductor memory device in which a capacitor is connected in parallel to a select transistor has been developed. This chain type semiconductor memory device allows high-speed write and read because the bit line capacitance can be reduced. However, the number of via contacts to select transistors increases. Consequently, as micropatterning progresses, the capacitor and via contact shortcircuit.

That is, the chain type semiconductor memory device has a capacitor for holding data, and a select transistor. The capacitor is made up of a lower electrode, an upper electrode, and a dielectric film formed between these electrodes. When the semiconductor memory device is a dynamic random access memory (DRAM), the dielectric film is made of, e.g., SiN, TaO₂, TiO₂, Al₂O₃, ZrO₂, or HfO₂. When the semiconductor memory device is a ferroelectric memory (FeRAM), the dielectric film is made of an oxide containing a perovskite structure, e.g., PZT (Pb(Zr,Ti)O₃), SBT (SrBi₂Ta₂O₉), or BIT (Bi₄Ti₃O₁₂), or an oxide in which any of these oxides is partially substituted with a substituent element.

The lower electrode of the capacitor is connected to the source (or drain) of the select transistor via a first contact plug. The upper electrode of the capacitor is connected to a metal interconnection running in the channel longitudinal direction of the selector transistor via a second contact plug. This metal interconnection is connected to the drain (or source) of the select transistor via a via contact. The lower electrode, dielectric film, and upper electrode forming the capacitor are partially extended to a position above a gate electrode forming the select transistor. Therefore, the via contact is formed at a distance by which the via contact and capacitor do not short.

The distance between the capacitor and via contact is set with a margin by taking lithography misalignment into consideration. However, this margin extremely decreases as element micropatterning advances. This poses the problem of short between the capacitor and via contact, so it is being desired to prevent this short between the capacitor and via contact.

In the technical field of semiconductor devices, a technique which prevents a leakage current between a contact and the gate of a transistor has been developed (e.g., Jpn. Pat. Appln. KOKAI Publication No. 2001-57422).

### BRIEF SUMMARY OF THE INVENTION

According to a first aspect of the invention, there is provided a semiconductor memory device comprising: a transistor formed in a surface region of a semiconductor substrate, and having a gate electrode and source/drain regions; a capacitor formed above the transistor, and selected by the transistor, the capacitor having a first electrode, a second electrode, and a dielectric film formed between the first and second electrodes; a first contact formed on a side surface portion of the capacitor so as to be close to at least a portion of the capacitor, the first contact being connected to one of the source/drain regions; and a sidewall insulating film formed, in contact with at least the capacitor, on sidewalls of the first contact.

According to a second aspect of the invention, there is provided a semiconductor memory device comprising: a transistor formed in a surface region of a semiconductor substrate, and having a gate electrode and source/drain regions; a capacitor formed above the transistor, having a first electrode, a second electrode, and a dielectric film formed between the first and second electrodes, and selected by the transistor; an insulating film formed on a side surface portion of the capacitor; and a first contact formed on the side surface portion of the capacitor so as to be partially in contact with the insulating film, and connected to one of the source/drain regions.

According to a third aspect of the invention, there is provided a semiconductor memory device fabrication method comprising: forming a transistor having a gate electrode and source/drain regions in a surface region of a semiconductor substrate; forming, on the semiconductor substrate, a first insulating film which covers the transistor; forming, in the first insulating film, a first contact connected to one of the source/drain regions; forming a first electrode material, dielectric film, and second electrode material sequentially on the first insulating film; etching the second electrode material, dielectric film, and first electrode material to form a capacitor having a first electrode, dielectric film, and second electrode; forming, on the first insulating film, a second insulating film which covers the capacitor; forming, in the second insulating film, a second contact connected to the second electrode; forming, in the second insulating film, a hole which is in contact with at least a portion of the capacitor, the hole exposing the other one of the source/drain regions; forming a third insulating film on inner side surfaces of the hole; and forming, in the hole, a third contact connected to the other one of the source/drain regions.

According to a fourth aspect of the invention, there is provided a semiconductor memory device fabrication method comprising: forming a transistor having a gate electrode and source/drain regions in a surface region of a semiconductor substrate; forming, on the semiconductor substrate, a first insulating film which covers the transistor; forming, in the first insulating film, a first contact connected to one of the source/drain regions; forming a first electrode material, dielectric film, and second electrode material sequentially on the first insulating film; etching the second electrode material, dielectric film, and first electrode material to form a capacitor having a first electrode, dielectric film, and second electrode; forming a second insulating film on a sidewall of the capacitor; forming, on the first insulating film, a third insulating film which covers the capacitor; forming, in the third insulating film, a second contact connected to the second electrode; forming, in the first and third insulating films, a hole which is in contact with at least a portion of the capacitor, the hole exposing the other one of the source/drain regions; and forming, in the hole, a third contact connected to the other one of the source/drain regions.

According to a fifth aspect of the invention, there is provided a semiconductor memory device fabrication method comprising: forming a transistor having a gate electrode and source/drain regions in a surface region of a semiconductor substrate; forming, on the semiconductor substrate, a first insulating film which covers the transistor; forming, in the first insulating film, a first contact connected to one of the source/drain regions; forming a first electrode material, dielectric film, and second electrode material sequentially on the first insulating film; etching the second electrode material, dielectric film, and first electrode material to form a capacitor having a first electrode, dielectric film, and second electrode; forming, on the first insulating film, a second insulating film which covers the capacitor; forming, in the second insulating film, a second contact connected to the second electrode; forming, in the first and third insulating films, a hole which is in contact with a sidewall of the capacitor, the hole exposing the other one of the source/drain regions; forming an insulating portion by oxidizing the sidewall of the capacitor from the hole; and forming, in the hole, a third contact connected to the other one of the source/drain regions.

According to a sixth aspect of the invention, there is provided a semiconductor memory device fabrication method comprising: forming a transistor having a gate electrode and source/drain regions in a surface region of a semiconductor substrate; forming, on the semiconductor substrate, a first insulating film which covers the transistor; forming, in the first insulating film, a first contact connected to one of the source/drain regions; forming a second insulating film on the first insulating film; forming, in the first and second insulating films, a second contact connected to the other one of the source/drain regions; forming a first electrode material, dielectric film, and second electrode material sequentially on the second insulating film; etching the second electrode material, dielectric film, and first electrode material to form a capacitor having a first electrode, dielectric film, and second electrode; forming, on the second insulating film, a third insulating film which covers the capacitor; forming, in the third insulating film, a third contact connected to the second electrode; forming, in the second and third insulating films, a hole which is in contact with a sidewall of the capacitor, the hole exposing the other one of the source/drain regions; forming a fourth insulating film on side surfaces of the hole; and forming, in the hole, a fourth contact connected to the first contact.

According to a seventh aspect of the invention, there is provided a semiconductor memory device fabrication method comprising: forming a transistor having a gate electrode and source/drain regions in a surface region of a semiconductor substrate; forming, on the semiconductor substrate, a first insulating film which covers the transistor; forming, in the first insulating film, a first contact connected to one of the source/drain regions, and a second contact connected to the other one of the source/drain regions; forming a first electrode material, dielectric film, and second electrode material sequentially on the first insulating film; etching the second electrode material, dielectric film, and first electrode material to form a capacitor having a first electrode connected to the first contact, a dielectric film, and a second electrode; forming, on the first insulating film, a second insulating film which covers the capacitor; forming, in the second insulating film, a third contact connected to the second electrode; forming, in the second insulating film, a hole which is in contact with a sidewall of the capacitor, the hole exposing an upper surface of the second contact; forming a third insulating film on side surfaces of the hole; and forming, in the hole, a fourth contact connected to the second contact.

### BRIEF DESCRIPTION OF THE SEVERAL VIEWS OF THE DRAWING

FIG. 1 is a sectional view showing an example of a semiconductor memory device according to the first embodiment;

FIG. 2 is a sectional view showing a method of fabricating the semiconductor memory device according to the first embodiment;

FIG. 3 is a sectional view showing a fabrication step following FIG. 2;

FIG. 4 is a sectional view showing a fabrication step following FIG. 3;

FIG. 5 is a sectional view showing a fabrication step following FIG. 4;

FIG. 6 is a sectional view showing a fabrication step following FIG. 5;

FIG. 7 is a sectional view showing an example of a semiconductor memory device according to the second embodiment;

FIG. 8 is a sectional view showing a method of fabricating the semiconductor memory device according to the second embodiment;

FIG. 9 is a sectional view showing an example of a semiconductor memory device according to the third embodiment;

FIG. 10 is a sectional view showing a method of fabricating the semiconductor memory device according to the third embodiment;

FIG. 11 is a sectional view showing an example of a semiconductor memory device according to the fourth embodiment;

FIG. 12 is a sectional view showing a method of fabricating the semiconductor memory device according to the fourth embodiment;

FIG. 13 is a sectional view showing a fabrication step following FIG. 12;

FIG. 14 is a sectional view showing a fabrication step following FIG. 13;

FIG. 15 is a sectional view showing an example of a semiconductor memory device according to the fifth embodiment;

FIG. 16 is a sectional view showing a fabrication step following FIG. 15;

FIG. 17 is a sectional view showing an example of a semiconductor memory device according to the sixth embodiment;

FIG. 18 is a sectional view showing a method of fabricating the semiconductor memory device according to the sixth embodiment;

FIG. 19 is a sectional view showing a fabrication step following FIG. 18;

FIG. 20 is a sectional view showing a fabrication step following FIG. 19;

FIG. 21 is a sectional view showing a fabrication step following FIG. 20;

FIG. 22 is a sectional view showing an example of a semiconductor memory device according to the seventh embodiment;

FIG. 23 is a sectional view showing a fabrication step following FIG. 22;

FIG. 24 is a sectional view showing a fabrication step following FIG. 23; and

FIG. 25 is a sectional view showing an example of semiconductor memory device according to the eighth embodiment.

### DETAILED DESCRIPTION OF THE INVENTION

Embodiments of the present invention will be descried below with reference to the accompanying drawing.

(First Embodiment)

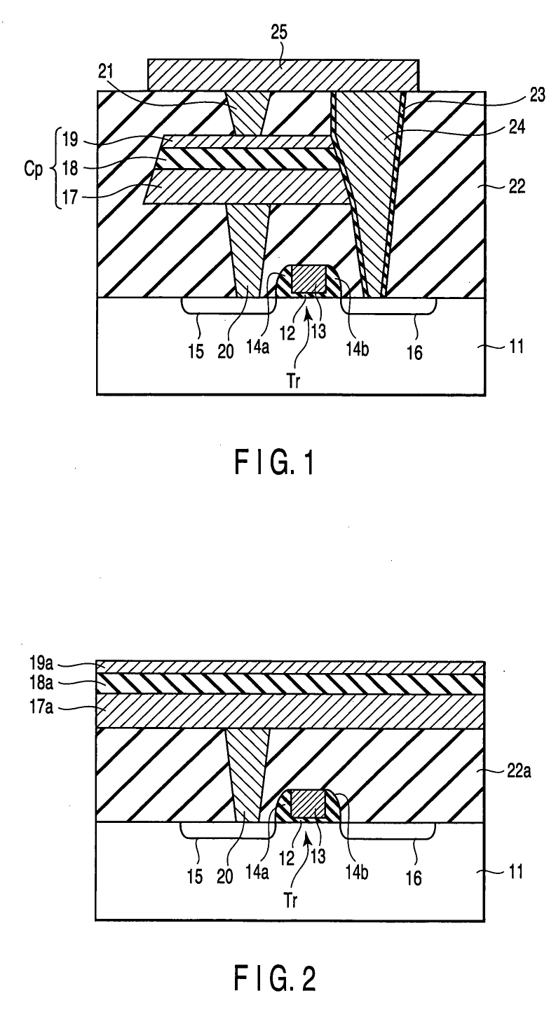

FIG. 1 shows an example of a semiconductor memory device according to the first embodiment. This semiconductor memory device is, e.g., a chain type device in which a capacitor Cp is connected in parallel to a select transistor Tr, and a COP (Capacitor On Plug) type device in which the capacitor Cp is positioned immediately above a contact plug connected to the select transistor Tr. Also, the capacitors Cp are, e.g., parallel plate, simultaneous processing type capacitors in which upper electrodes, dielectric films, or lower electrodes are simultaneously processed.

Referring to FIG. 1, the select transistor Tr is formed in a surface region of a semiconductor substrate 11 made of, e.g., silicon. The select transistor Tr is made up of a gate insulating film 12 such as a silicon oxide film, a gate electrode 13 on the gate insulating film 12, sidewall insulating films 14a and 14b formed on the sidewalls of the gate electrode 13, and source/drain regions 15 and 16 formed in the semiconductor substrate 11.

The capacitor Cp is made up of a lower electrode 17, dielectric film 18, and upper electrode 19. A portion of the capacitor Cp extends to a position above the gate electrode 13 of the select transistor Tr. The lower electrode 17 of the capacitor Cp is connected to the source/drain region 15 of the select transistor Tr via a contact plug 20. The select transistor Tr, capacitor Cp, and contact plug 20 are covered with an interlayer dielectric film 22. A contact 21 connected to the upper electrode 19 is formed in the interlayer dielectric film 22. In addition, a via contact 24 connected to the source/drain region 16 is formed in the interlayer dielectric film 22, and a sidewall insulating film 23 is formed on the sidewalls of the via contact 24. The via contact 24 and contact 21 are connected to an interconnection layer 25 formed on the interlayer dielectric film 22.

In a chain type device in which the capacitor Cp and select transistor Tr are connected in parallel to each other, two adjacent capacitors Cp can alternately share the upper electrode 19 and lower electrode 17. However, if the via contact 24 for connecting the upper electrode 19 and select transistor Tr comes in contact with the lower electrode 17, no voltage is applied to the capacitor Cp any longer. Therefore, the via contact 24 cannot be in electrical contact with the lower electrode 17. For this reason, the sidewall insulating film 23 is formed on the sidewalls of the via contact 24. The sidewall insulating film 23 is made of, e.g., Al₂O₃, SiO₂, or SiN. However, the material is not limited to these materials, and any highly insulating material can be used.

A method of fabricating the semiconductor memory device according to the first embodiment will be described below with reference to FIGS. 2 to 6.

As shown in FIG. 2, in a surface region of a semiconductor substrate 11, a select transistor Tr having a gate insulting film 12, gate electrode 13, sidewall insulating films 14a and 14b, and source/drain regions 15 and 16 is formed by using the conventional CMOS technique. After that, an interlayer dielectric film 22a covering the select transistor Tr is formed on the semiconductor substrate 11, and planarized. Subsequently, a hole (not shown) for exposing the source/drain region 15 is formed in the interlayer dielectric film 22a, and a material for forming a contact plug 20 is buried in this hole. The structure is then planarized by removing the material outside the hole, thereby forming a contact plug 20.

Subsequently, a lower electrode material 17a, dielectric film 18a, and upper electrode material 19a are formed sequentially on the interlayer dielectric film 22a. The upper electrode material 17a is, e.g., Pt, Ir, or IrO₂. When the semiconductor memory device is a dynamic random access memory (DRAM), the dielectric film 18a is made of, e.g., SiN, TaO₂, TiO₂, Al₂O₃, ZrO₂, or HfO₂. When the semiconductor memory device is a ferroelectric memory (FeRAM), the dielectric film 18a is made of an oxide containing a perovskite structure, e.g., PZT (Pb(Zr,Ti)O₃), SBT (SrBi₂Ta₂O₉), or BIT (Bi₄Ti₃O₁₂), or an oxide in which any of these oxides is partially substituted with a substituent element. The upper electrode material 19a is, e.g., Pt, Ir, or IrO₂. The lower electrode material 17a and upper electrode material 19a are formed by, e.g., sputtering. The dielectric film 18a is formed by, e.g., CVD (Chemical Vapor Deposition), spin coating such as a sol-gel method, or CSD (Chemical Solution Deposition).

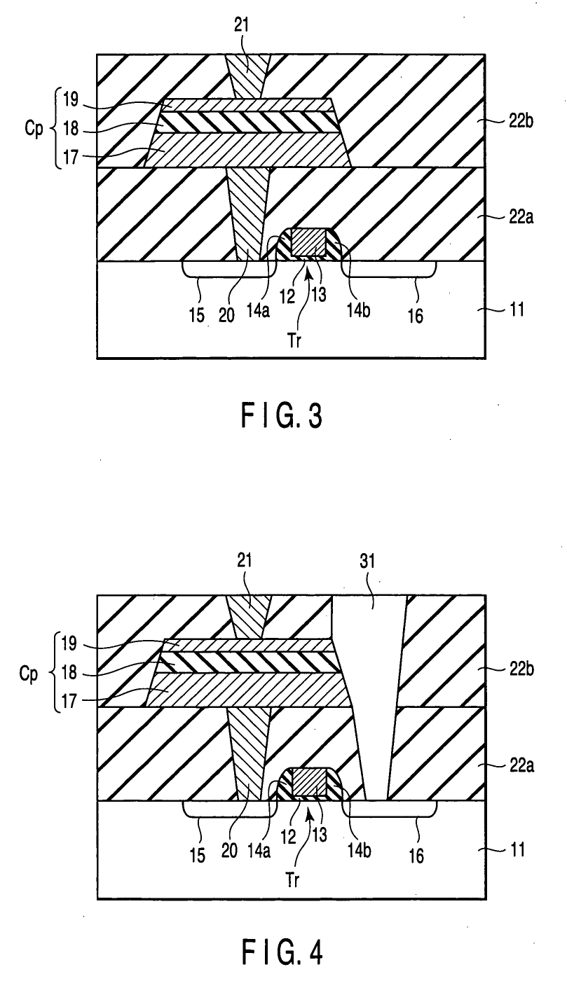

As shown in FIG. 3, the upper electrode material 19a, dielectric film 18a, and lower electrode material 17a are etched by RIE to form a capacitor Cp having an upper electrode 19, dielectric film 18, and lower electrode 17. As a mask of this etching, it is possible to use a photoresist or a hard mask, such as SiO₂, Al₂O₃, or TiAlN, which can resist high temperatures. When the hard mask is used, RIE can be performed at a high temperature and a high vapor pressure. The capacitor Cp formed by this etching is positioned immediately above the contact plug 20, and a portion of the capacitor Cp extends from a position above the gate electrode to a position above the source/drain region 16 of the select transistor Tr. Also, the side surfaces of the capacitor Cp are inclined, and the lower capacitor 17 is connected to the contact plug 20.

After that, an interlayer dielectric film 22b covering the capacitor Cp is deposited on the interlayer dielectric film 22a, and the surface of the interlayer dielectric film 22b is planarized by, e.g., CMP. Then, a hole (not shown) for exposing the upper electrode 19 is formed in the interlayer dielectric film 22b. A metal material such as Al or W is buried in this hole, and an unnecessary metal material is removed by, e.g., CMP, thereby forming a contact 21 connected to the upper electrode 19.

As shown in FIG. 4, a hole 31 for exposing the source/drain region 16 of the select transistor Tr is formed in the interlayer dielectric films 22b and 22a by using, e.g., RIE. In the first embodiment, the RIE conditions for forming the hole 31 use a gas system which can etch the interlayer dielectric films 22b and 22a and hardly etches the upper electrode 19, dielectric film 18, and lower electrode 17. Consequently, the diameter of that portion of the hole 31, which is formed in the interlayer dielectric film 22a below the lower electrode 17 is smaller than the diameter of that portion of the hole 31, which is formed above the lower electrode 17.

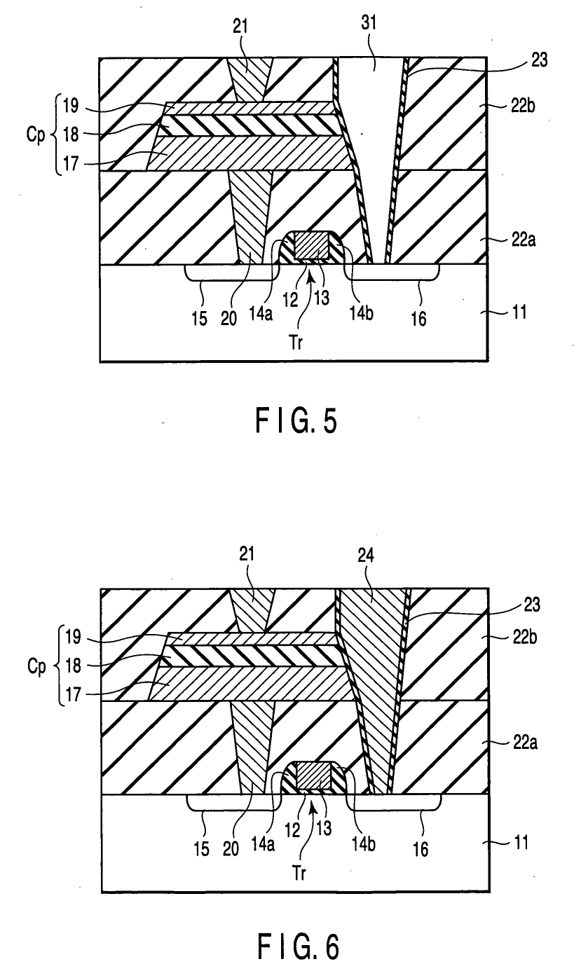

As shown in FIG. 5, a sidewall insulating film 23 made of, e.g., SiO₂, Al₂O₃, or SiN is formed on the sidewalls and bottom portion of the hole 31 by a high-coverage method such as CVD or ALD (Atomic Layer Deposition). The film thickness of the sidewall insulating film 23 must be thin to such an extent that a via contact and the capacitor Cp do not electrically short, and, because the diameter of the lower portion of the via contact is small, must be large to such an extent that the hole is not filled. Then, as shown in FIG. 5, the sidewall insulating film 23 on the source/drain region 16 is removed by using, e.g., RIE.

After that, as shown in FIG. 6, a metal material such as Al or W is buried in the hole 31, and an unnecessary metal material is removed by, e.g., CMP, thereby forming a via contact 24. Subsequently, a metal material such as Al or Cu is formed on the interlayer dielectric film 22b by, e.g., sputtering. This metal material is then etched by RIE or the like to form an interconnection layer 25 which connects the via contact 24 and contact 21.

Note that the interconnection layer 25 is formed in the step different from the step of forming the via contact 24, but the present invention is not limited to this method. For example, it is also possible to simultaneously form the via contact 24 and interconnection layer 25 by using, e.g., the damascene method.

In the first embodiment as described above, the sidewall insulating film 23 is formed on the sidewalls of the via contact 24. Therefore, even if positional deviation of lithography occurs when the distance between the capacitor Cp and via contact 24 is shortened by micropatterning of elements, an electrical shortcircuit between the via contact 24 and capacitor Cp can be prevented.

(Second Embodiment)

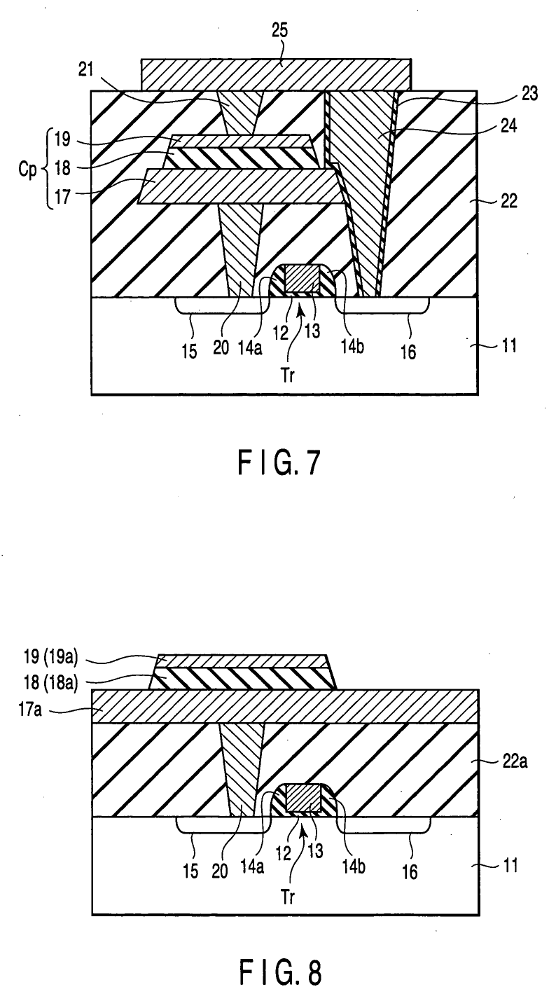

FIG. 7 shows an example of a semiconductor memory device according to the second embodiment. The structure of this semiconductor memory device is the same as the first embodiment except for the shapes of a capacitor Cp and via contact 24.

In the capacitor Cp shown in FIG. 7, the areas of a dielectric film 18 and upper electrode 19 are smaller than that of a lower electrode 17. Also, a sidewall insulating film 23 on the sidewalls of the via contact 24 is in contact only with the lower electrode 17.

A method of fabricating the semiconductor memory device having the above structure is the same as the first embodiment except for the fabrication step of the capacitor Cp.

FIG. 8 shows the fabrication step of the capacitor Cp. Referring to FIG. 8, after an interlayer insulating film 22a covering a select transistor Tr and a contact plug 20 are formed, a lower electrode material 17a, dielectric film 18a, and upper electrode material 19a are formed sequentially on the interlayer insulating film 22a. Then, as shown in FIG. 8, the upper electrode material 19a and dielectric film 18a are etched, and the lower electrode material 17a is etched after that. Consequently, as shown in FIG. 7, a lower electrode 17 having an area larger than those of an upper electrode 19 and dielectric film 18 is formed. Subsequently, a via contact 24 is formed by the same fabrication step as in the first embodiment.

In the second embodiment, the sidewall insulating film 23 is formed on the sidewalls of the via contact 24, so a shortcircuit between the via contact 24 and capacitor Cp can be prevented. In addition, the areas of the dielectric film 18 and upper electrode 19 are smaller than that of the lower electrode 17. This increases the margin for a direct short resistance between the upper electrode 19 and lower electrode 17.

In the example shown in FIG. 7, only the lower electrode 17 is in contact with the sidewall insulating film 23 on the sidewalls of the via contact 24. However, the sidewall insulating film 23 may also be in contact with the side surfaces of the dielectric film 18 and upper electrode 19.

(Third Embodiment)

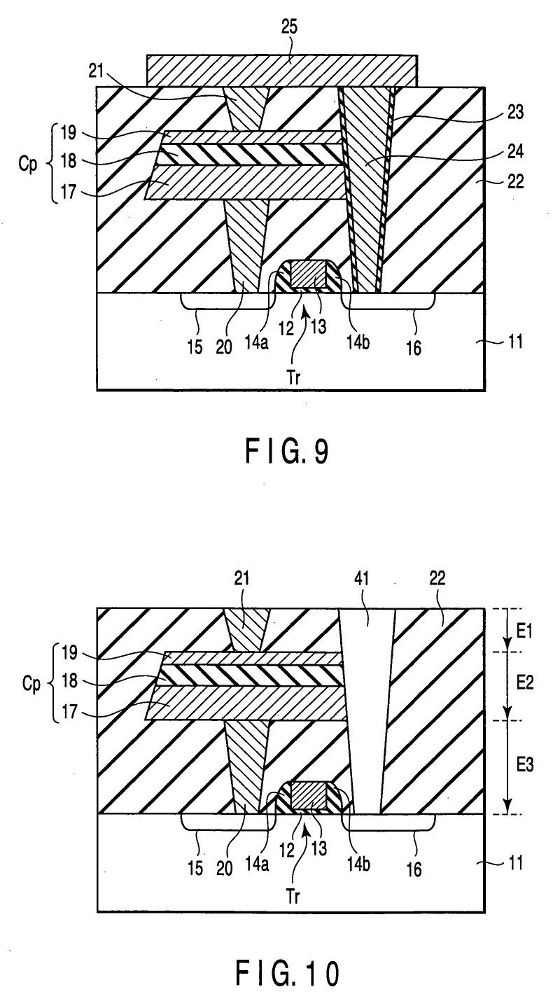

FIG. 9 shows an example of a semiconductor memory device according to the third embodiment. The structure of this semiconductor memory device is the same as the first embodiment except for the structures of a capacitor Cp and via contact 24.

In the first embodiment, the diameter of the via contact 24 positioned below the lower electrode 17 does not continuously gradually decreases the diameter of the via contact 24 has a step. By contrast, in the third embodiment as shown in FIG. 9, the via contact 24 positioned below a lower electrode 17 has no step and gradually decreases.

FIG. 10 shows a fabrication method of the third embodiment. The steps of the third embodiment are the same as the first embodiment except for the step of forming a via contact hole 41.

Referring to FIG. 10, the via contact hole 41 is formed as follows. First, an interlayer insulating film 22 is etched by RIE by using a gas having a high selectivity to the interlayer insulating film 22 (E1). When this etching nearly reaches the capacitor Cp, the etching gas is switched to a gas capable of etching an upper electrode 19, dielectric film 18, and lower electrode 17 forming the capacitor Cp, thereby etching both the interlayer dielectric film 22 and capacitor Cp (E2). When this etching including the capacitor Cp is complete, the etching gas is returned to the gas system for the interlayer insulating film 22 to etch only the interlayer insulating film 22 (E3). After that, a sidewall insulating film 23 and via contact 24 are formed sequentially in the hole 41 in the same manner as in the first embodiment.

In the third embodiment as described above, the etching gases are switched between the range (E1 and E3) in which only the interlayer insulating film 22 is etched and the range (E2) in which both the capacitor Cp and interlayer insulating film 22 are etched, thereby etching both the capacitor Cp and interlayer insulating film 22. This makes it possible to prevent the diameter of the hole 41 positioned below the lower electrode 17 from being extremely decreased, and to form the via contact 24 having no step. Since the diameter of the via contact 24 positioned below the lower electrode 17 can be ensured, it is possible to reliably connect the via contact 24 to a source/drain region 16 of a select transistor Tr, and increase the yield.

(Fourth Embodiment)

FIG. 11 shows an example of a semiconductor memory device according to the fourth embodiment. In the first to third embodiments, a shortcircuit between the via contact 24 and capacitor Cp is prevented by forming the sidewall insulating film 23 on the inner side surfaces of the holes 31 and 41, i.e., on the sidewalls of the via contact 24. By contrast, in the first embodiment, an insulating film 51 is formed on the side surfaces of a capacitor Cp without forming any sidewall insulating film on the sidewalls of a via contact 24. The insulating film 51 prevents a shortcircuit between the via contact 24 and capacitor Cp.

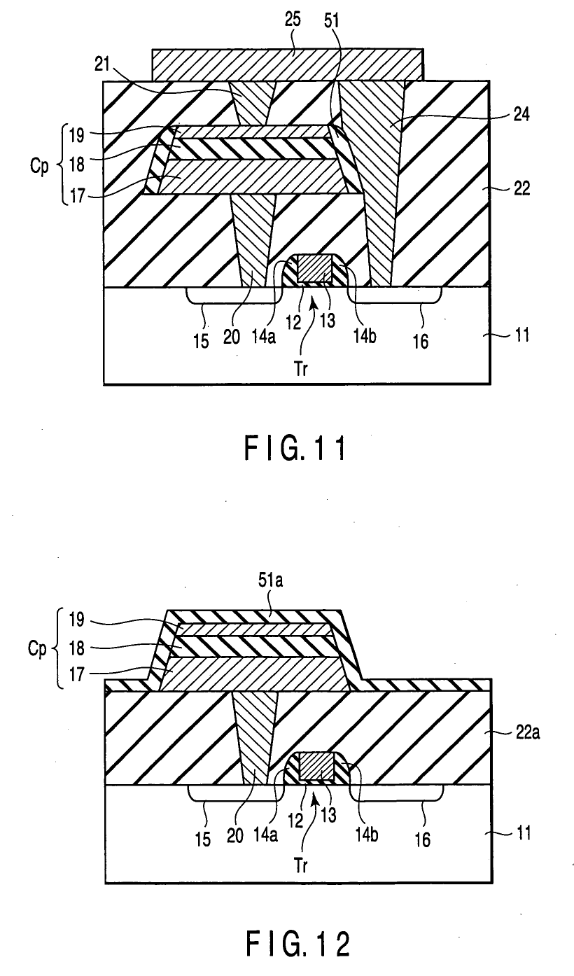

FIGS. 12 to 14 illustrate an example of a method of fabricating the semiconductor memory device shown in FIG. 11. The fabrication steps up to the formation of a capacitor Cp are the same as in the first embodiment.

As shown in FIG. 12, after the capacitor Cp is formed, an insulating film 51a covering the capacitor Cp is deposited on an interlayer insulating film 22a by using a high-coverage film formation method such as CVD or ALD. The insulating film 51a is made of, e.g., Al₂O₃ or SiN, and can be any insulating film as long as a high selectivity to the interlayer insulating film 22a is obtained. Also, the insulating film 51a has a film thickness by which the capacitor Cp and via contact 24 can be insulated.

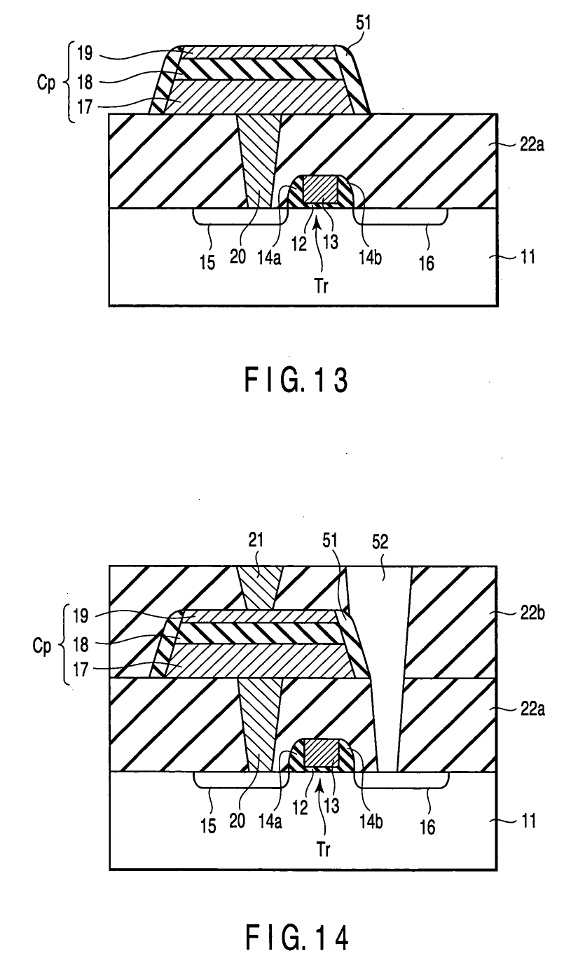

As shown in FIG. 13, an extra portion in the horizontal direction of the insulating film 51a is removed by using, e.g., RIE. In this step, the insulating film 51a on the sidewalls of the capacitor Cp can also recede. If a gas system by which this can occur is used in etching, the insulating film 51a having a large thickness must be deposited in advance. In this manner, an insulating film 51 is formed on the sidewalls of the capacitor Cp.

If the angle of the inclination formed on the sidewalls of the capacitor Cp is small, the insulating film 51a is easily etched. Therefore, the sidewalls of the capacitor Cp must be as close to vertical as possible.

As shown in FIG. 14, in the same manner as in the first embodiment, an interlayer insulating film 22b covering the capacitor Cp is formed on the interlayer insulating film 22a and planarized. A contact 21 connected to an upper electrode 19 is formed in the interlayer insulating film 22b. After that, a hole 52 for exposing a source/drain region 16 is formed in the interlayer insulating films 22b and 22a. When the hole 52 is formed by RIE, it is necessary to etch only the interlayer insulating films 22b and 22a without etching the insulating film 51 formed on the sidewalls of the capacitor Cp. Accordingly, a fluorine-based gas, for example, is used in this etching. After that, the hole 52 is filled with a metal material such as Al or Cu, and an extra metal material is removed by CMP, thereby forming the via contact 24 shown in FIG. 11. Then, an interconnection layer 25 for connecting the via contact 24 and contact 21 is formed.

Note that as in the first embodiment, the interconnection layer 25 may also be formed simultaneously with the via contact 24 by using, e.g., the damascene method.

Also, after the insulating film 51a is formed, the hole 52 can be formed by removing the insulating film 51a together with the interlayer insulating films 22a and 22b, without performing etching which forms an insulating film 51 on the sidewalls of the capacitor Cp. In this case, it is necessary to use a gas system capable of etching both the interlayer insulating films 22a and 22b and the insulating film 51a.

In the fourth embodiment described above, the insulating film 51 is formed on the sidewalls of the capacitor Cp. Therefore, no insulating film need be formed on the side surfaces of the via contact 24, i.e., on the side surfaces of the hole 52 having a high aspect ratio. This facilitates the fabrication. In addition, if an insulating film is formed in the hole 52, this insulating film may remain on the bottom portion of the hole 52 to cause poor contact. However, the fourth embodiment can avoid poor contact and increase the yield.

(Fifth Embodiment)

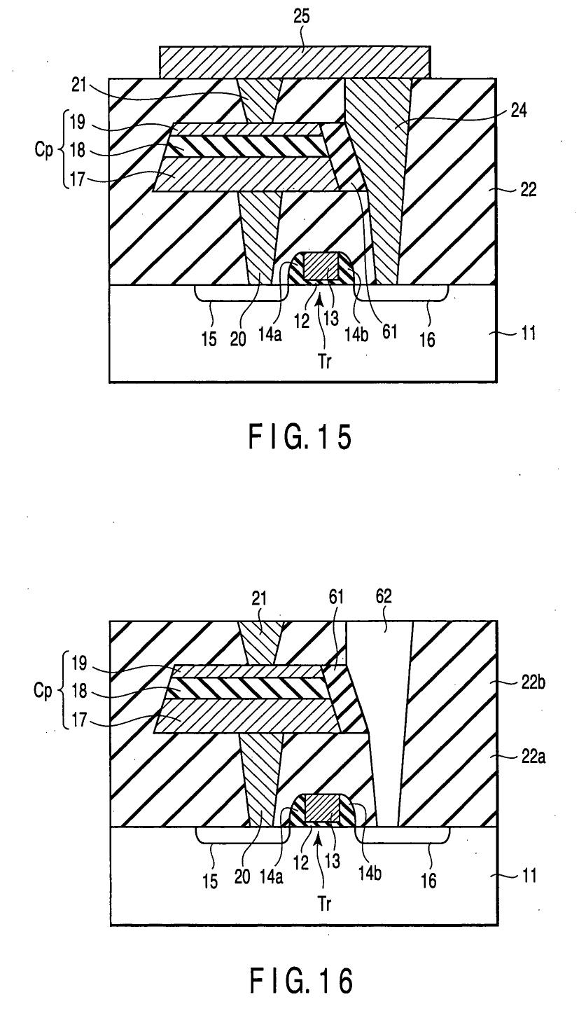

FIG. 15 shows an example of a semiconductor memory device according to the fifth embodiment. The structures of a select transistor Tr and capacitor Cp are the same as in the first and fourth embodiments except that an insulating portion 61 in contact with a via contact 24 is formed on the sidewall of the capacitor Cp unlike in the fourth embodiment.

FIG. 16 shows a method of fabricating the semiconductor memory device according to the fifth embodiment. The fabrication steps up to the formation of a hole 62 are the same as in the first embodiment. After that, a chemical reaction such as oxidation or liquid chemical processing is performed, via the hole 62, to partially oxidize a lower electrode 17, dielectric film 18, and upper electrode 19 positioned on the sidewall of a capacitor Cp, thereby forming an insulating portion 61. After the oxide film on the bottom portion of the hole 62 is removed, a via contact 24 and interconnection layer 25 are formed in the same manner as in the fourth embodiment.

The above fifth embodiment can achieve the same effects as in the fourth embodiment. In addition, since the insulating film 61 is formed by partially insulating the sidewall of the capacitor Cp, no insulating film need be formed separately from the capacitor Cp. Accordingly, the capacitor Cp and via contact 24 can be reliably insulated without increasing the spacing between the capacitor Cp and via contact 24 by an insulating film, or decreasing the size of the capacitor.

(Sixth Embodiment)

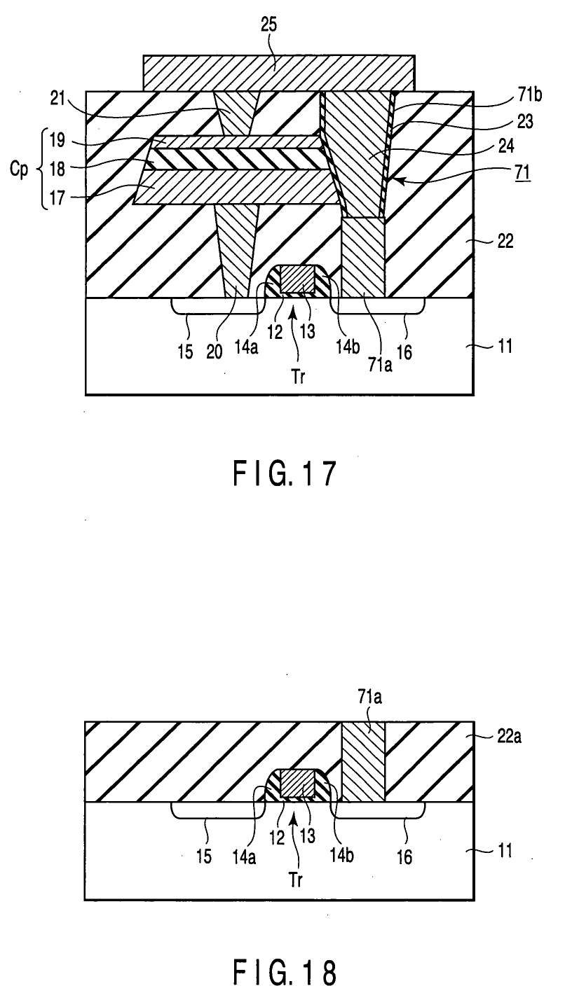

FIG. 17 shows an example of a semiconductor memory device according to the sixth embodiment. In the sixth embodiment, a capacitor Cp and select transistor Tr are the same as in the first embodiment, and the structure and fabrication method of a via contact 71 for connecting an interconnection layer 25 and source/drain region 16 are different from the first embodiment.

That is, referring to FIG. 17, the via contact 71 includes a first portion 71a formed from a semiconductor substrate 11 (source/drain region 16) to a position below the capacitor Cp, and a second portion 71b formed between the first portion 71a and interconnection layer 25. As in the first embodiment, the second portion 71b is made up of a via contact 24 and sidewall insulating film 23. The via contact 24 and sidewall insulating film 23 extend downward from the capacitor Cp.

FIGS. 18 to 21 illustrate a method of fabricating the semiconductor memory device according to the sixth embodiment.

As shown in FIG. 18, a select transistor Tr is formed in a surface region of a semiconductor substrate 11. After that, an interlayer insulating film 22a covering the select transistor Tr is formed on the semiconductor substrate 11 and planarized. Then, a first portion 71a of a via contact 71 connected to a source/drain region 16 is formed in the interlayer insulating film 22a. That is, a hole (not shown) for exposing the source/drain region 16 is formed in the interlayer insulating film 22a and filled with a metal material, and the metal material outside the hole is removed by, e.g., CMP.

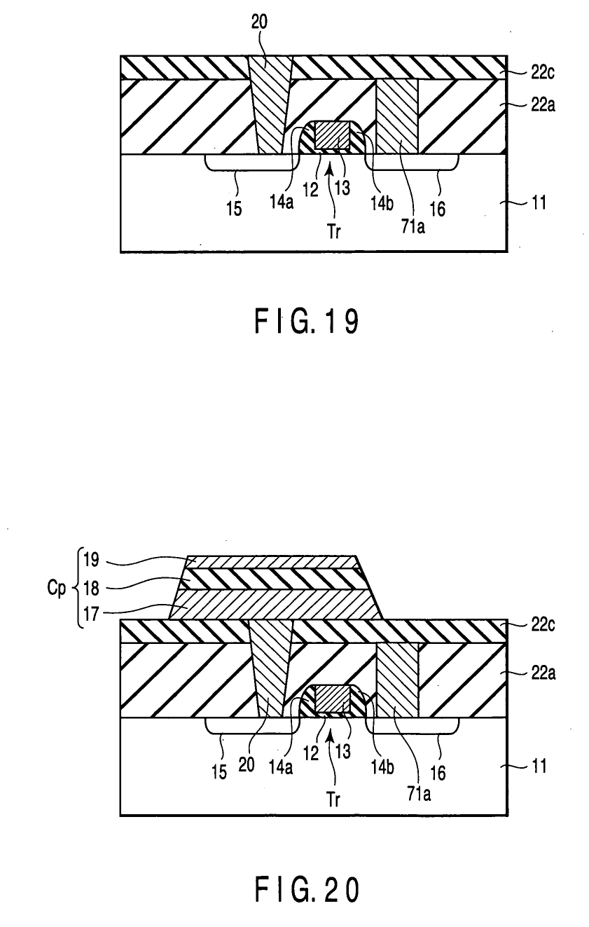

After that, as shown in FIG. 19, an interlayer insulating film 22c is formed on the interlayer insulating film 22a. The material of the interlayer insulating film 22c is the same as the interlayer insulating film 22a, e.g., SiO₂. Then, a contact plug 20 connected to a source/drain region 15 is formed in the interlayer insulating films 22b and 22a. The formation method of the contact plug 20 is the same as the first portion 71a.

As shown in FIG. 20, in the same manner as in the first embodiment, a capacitor Cp is formed on the interlayer insulating film 22c, and a lower electrode 17 of the capacitor Cp is connected to the contact plug 20.

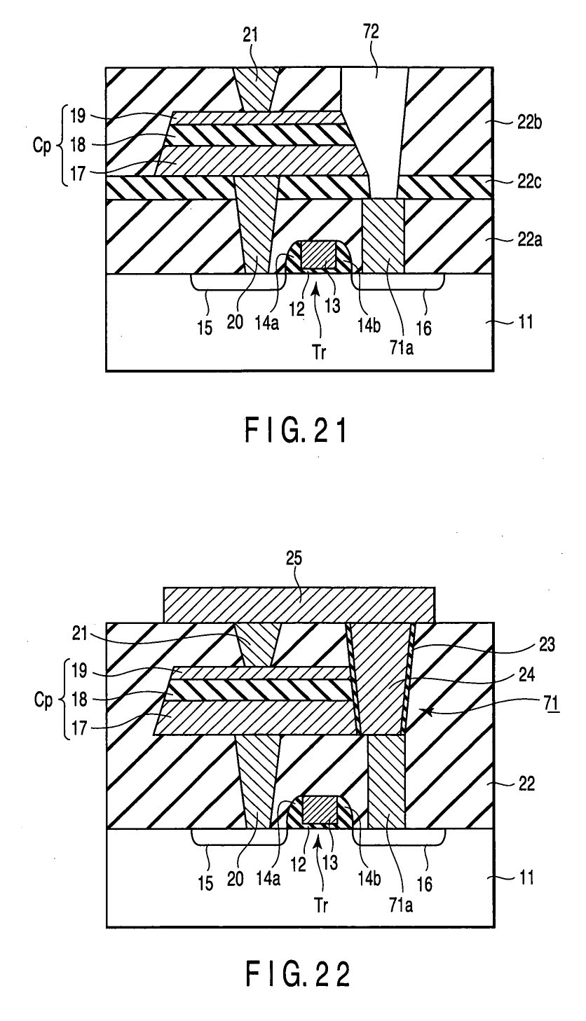

After that, as shown in FIG. 21, an interlayer insulating film 22b covering the capacitor Cp is formed on the interlayer insulating film 22c. In the same manner as in the first embodiment, a contact 21 connected to an upper electrode 19 of the capacitor Cp is formed in the interlayer insulating film 22b. Subsequently, in the same manner as in the first embodiment, a second portion 71b of a via contact is formed in the interlayer insulating films 22b and 22c. That is, the interlayer insulating films 22b and 22c are etched by RIE to form a hole 72 in the interlayer insulating films 22b and 22c. The hole 72 exposes the upper surface of the first portion 71a of the via contact 71. The etching conditions are set such that the selectivity to the interlayer insulating films 22b and 22 is high. Accordingly, the capacitor Cp is rarely etched, a step is formed in the middle of the hole 72, and the diameter of the lower portion of the hole 72 is made smaller than that of its upper portion by the capacitor Cp.

As shown in FIG. 22, a sidewall insulating film 23 is formed on the sidewalls of the hole 72, and a metal material is buried in the hole 72 and planarized. Then, an interconnection layer 25 which connects the second portion 71b and contact 21 is formed.

In the sixth embodiment described above, the via contact 71 includes the first portion 71a from the semiconductor substrate 11 (source/drain region 16) to the position below the capacitor Cp, and the second portion 71b between the first portion 71a and interconnection layer 25. The first portion 71a is formed beforehand, and then the second portion 71b is formed. Although this slightly increases the number of fabrication steps, it is possible to decrease the aspect ratio of the hole which is formed during the formation of the first and second portions 71a and 71b. Therefore, it is possible to reliably bury the metal material in each hole, reduce poor contacts, and increase the yield.

In the sixth embodiment, the capacitor Cp and via contact 71 are insulated by the sidewall insulating film 23 formed on the sidewalls of the second portion 71b of the via contact. However, the present invention is not limited to this structure. For example, an insulating film may also be formed on the side surfaces of the capacitor as in the fourth embodiment, or a method of insulating a portion of the capacitor may also be used.

(Seventh Embodiment)

FIG. 22 shows an example of a semiconductor memory device according to the seventh embodiment.

In the sixth embodiment, to avoid a shortcircuit between the first portion 71a of the via contact 71 and the capacitor Cp, the first portion 71a is formed below the lower electrode 17 of the capacitor Cp. Therefore, the first portion 71a of the via contact 71 and the contact plug 20 are formed in different steps. By contrast, in the seventh embodiment, it is possible to avoid a shortcircuit between a first portion 71a of a via contact 71 and a capacitor Cp, and simultaneously form the first portion 71a of the via contact 71 and a contact plug 20.

As shown in FIG. 22, the upper surface of the first portion 71a of the via contact 71 is leveled with the upper surface of the contact plug 20. Also, a second portion 71b of the via contact 71 is formed by slightly removing the side surface of the capacitor Cp. This makes the diameter of the bottom portion of the second portion 71b larger than that in the sixth embodiment. Accordingly, the distance in the horizontal direction between the upper surface of the first portion 71a and the lower electrode 17 of the capacitor Cp is larger than that in the sixth embodiment.

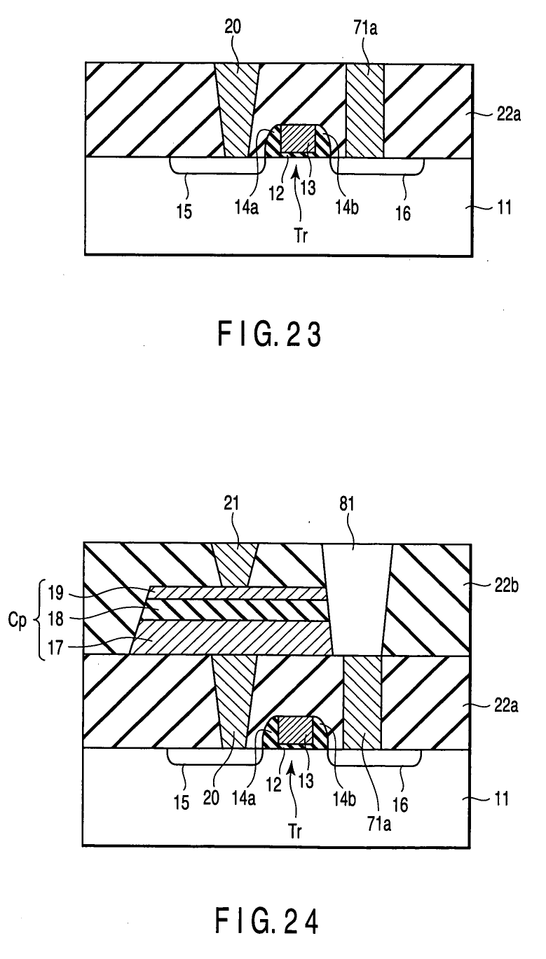

FIGS. 23 and 24 illustrate a method of fabricating the semiconductor memory device according to the seventh embodiment. As shown in FIG. 23, a select transistor Tr is formed in a surface region of a semiconductor substrate 11, and an interlayer insulating film 22a covering the select transistor Tr is formed on the semiconductor substrate 11 and planarized. Subsequently, a contact plug 20 connected to a source/drain region 15 and a first portion 71a of a via contact 71 connected to a source/drain region 16 are formed in the interlayer insulating film 22a. That is, holes for exposing the source/drain regions 15 and 16 are formed in the interlayer insulating film 22a, a metal material is buried in these holes, and the metal material outside the holes is removed by CMP or the like.

As shown in FIG. 24, in the same manner as in the first embodiment, a capacitor Cp is formed on the interlayer insulating film 22a, and a lower electrode 17 of the capacitor Cp is connected to the contact plug 20. After that, an interlayer insulating film 22b covering the capacitor Cp is formed on the interlayer insulating film 22a. In the same manner as in the first embodiment, a contact 21 connected to an upper electrode 19 of the capacitor Cp is formed in the interlayer insulating film 22b.

Then, a second portion 71b of the via contact is formed in the interlayer insulating film 22b following the same procedure as in the fourth embodiment. That is, the interlayer insulating film 22b is etched by RIE to form a hole 81 in the interlayer insulating film 22b. The hole 81 exposes the upper surface of the first portion 71a of the via contact 71. This etching is performed by using a gas system which etches both the interlayer insulating film 22b and capacitor Cp. This makes the diameter of the lower portion of the hole 81 larger than that in the sixth embodiment without forming any step in the middle of the hole 81. Then, as shown in FIG. 22, a sidewall insulating film 23 is formed on the sidewalls of the hole 81, and a metal material 24 is buried in the hole 81 and planarized. After that, an interconnection layer 25 which connects the second 71b and contact 21 is formed.

In the seventh embodiment described above, the second portion 71b of the via contact 71 is formed by slightly removing the side surface of the capacitor Cp, so the diameter of the bottom portion of the second portion 71b is larger than that in the sixth embodiment. Accordingly, the distance in the horizontal direction between the upper surface of the first portion 71a and the lower electrode 17 of the capacitor Cp can be made larger than that in the sixth embodiment. Therefore, even when the first portion 71a of the via contact 71 and the contact plug 20 are simultaneously formed, a shortcircuit between the first portion 71a of the via contact 71 and the capacitor Cp can be avoided.

Additionally, since the diameter of the bottom portion of the second portion 71b of the via contact 71 is large, the connection margin with the first portion 71a can be increased. This makes reliable formation of the via contact 71 feasible.

Furthermore, since the first portion 71a of the via contact 71 and the contact plug 20 can be simultaneously formed, the number of fabrication steps can be made smaller than that in the sixth embodiment.

(Eighth Embodiment)

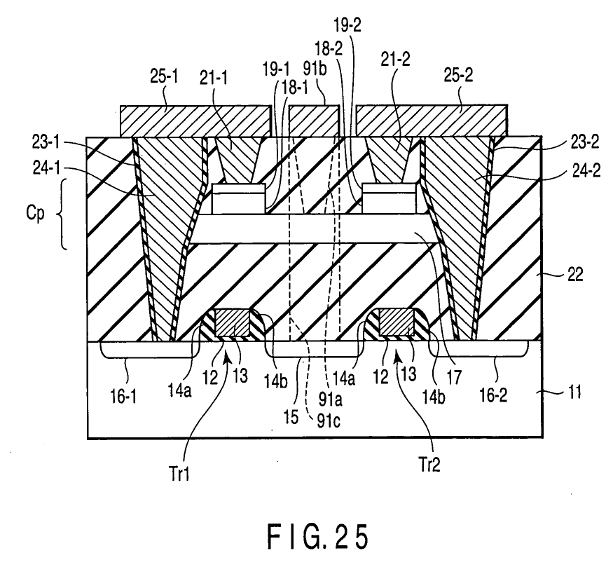

FIG. 25 shows an example of a semiconductor memory device according to the eighth embodiment. In the eighth embodiment, the first embodiment is applied to a chain type semiconductor device in which a contact of a lower electrode is offset in, e.g., the widthwise direction of a gate electrode. Therefore, the same reference numerals as in the first embodiment denote the same parts.

Referring to FIG. 25, select transistors Tr1 and Tr2 are formed in a surface region of a semiconductor substrate 11. Capacitors Cp1 and Cp2 are formed above the select transistors Tr1 and Tr2, respectively. In the capacitors Cp1 and Cp2, dielectric films 18-1 and 18-2 are formed on a common lower electrode 17, and upper electrodes 19-1 and 19-2 are formed on the dielectric films 18-1 and 18-2, respectively. The select transistors Tr1 and Tr2 and capacitors Cp1 and Cp2 are covered with an interlayer insulating film 22.

A contact 91a connected to the upper surface of the lower electrode 17 is formed in the interlayer insulating film 22. The contact 91a is connected to a common source/drain diffusion layer 15 of the select transistors Tr1 and Tr2 via an interconnection 91b and via contact 91c.

Contacts 21-1 and 21-2 are connected to the upper electrodes 19-1 and 19-2, respectively. Via contacts 24-1 and 24-2 having the same structure as in the first embodiment are connected to source/drain regions 16-1 and 16-2 of the select transistors Tr1 and Tr2, respectively. On the sidewalls of the via contacts 24-1 and 24-2, sidewall insulating films 23-1 and 23-2 which insulate the lower electrode 17 and via contacts 24-1 and 24-2, respectively, are formed.

In the eighth embodiment, the sidewall insulating films 23-1 and 23-2 are formed on the sidewalls of the via contacts 24-1 and 24-2. In a chain type, offset type semiconductor memory device, therefore, the capacitor Cp and via contacts 24-1 and 24-2 can be reliably insulated even when elements are micropatterned.

In the eighth embodiment, the first embodiment is applied to a chain type, offset type semiconductor memory device. However, the second to seventh embodiments can also be applied.

In each of the first to eighth embodiments described above, a chain type semiconductor memory device in which a capacitor is connected in parallel to a select transistor is explained. However, the present invention is not limited to this chain type semiconductor memory device. That is, the first to eighth embodiments can be applied to any semiconductor memory device in which the spacing between a capacitor and via contact is narrow.

Furthermore, in each of the first to eighth embodiments, Al or W, for example, is used as the via contacts and interconnections. However, it is also possible to use, e.g., Cu. In this case, via contacts and interconnections are simultaneously formed by using the dual damascene technique, and unnecessary Cu is removed by CMP after that.

Also, the first to eighth embodiments are applicable to both a ferroelectric memory and DRAM.

Additional advantages and modifications will readily occur to those skilled in the art. Therefore, the invention in its broader aspects is not limited to the specific details and representative embodiments shown and described herein. Accordingly, various modifications may be made without departing from the spirit and scope of the general inventive concept as defined by the appended claims and their equivalents.

What is claimed is:

1. A semiconductor memory device comprising:
a transistor formed in a surface region of a semiconductor substrate, and having a gate electrode and source/drain regions;
a capacitor formed above the transistor, and selected by the transistor, the capacitor having a first electrode, a second electrode, and a dielectric film formed between the first and second electrodes;
a first contact formed on a side surface portion of the capacitor so as to be close to at least a portion of the capacitor, the first contact being connected to one of the source/drain regions; and
a sidewall insulating film formed, in contact with at least the capacitor, on sidewalls of the first contact.

2. A device according to claim 1, wherein the insulating film extends downward from the side surface portion of the capacitor.

3. A device according to claim 1, further comprising:
a second contact connected to the first electrode and the other one of the source/drain regions;
a third contact formed on the second electrode; and
an interconnection which connects the first and third contacts.

4. A device according to claim 1, wherein the second contact is offset from the capacitor.

5. A device according to claim 1, wherein the dielectric film is a ferroelectric film.

6. A semiconductor memory device comprising:
a transistor formed in a surface region of a semiconductor substrate, and having a gate electrode and source/drain regions;
a capacitor formed above the transistor, having a first electrode, a second electrode, and a dielectric film formed between the first and second electrodes, and selected by the transistor;
an insulating film formed on a side surface portion of the capacitor; and
a first contact formed on the side surface portion of the capacitor so as to be partially in contact with the insulating film, and connected to one of the source/drain regions.

7. A device according to claim 6, further comprising:
a second contact connected to the first electrode and the other one of the source/drain regions;
a third contact formed on the second electrode; and
an interconnection which connects the first and third contacts.

8. A device according to claim 6, wherein the dielectric film is a ferroelectric film.

9. A semiconductor memory device fabrication method comprising:
forming a transistor having a gate electrode and source/drain regions in a surface region of a semiconductor substrate;
forming, on the semiconductor substrate, a first insulating film which covers the transistor;
forming, in the first insulating film, a first contact connected to one of the source/drain regions;
forming a first electrode material, dielectric film, and second electrode material sequentially on the first insulating film;
etching the second electrode material, dielectric film, and first electrode material to form a capacitor having a first electrode, dielectric film, and second electrode;
forming, on the first insulating film, a second insulating film which covers the capacitor;
forming, in the second insulating film, a second contact connected to the second electrode;
forming, in the second insulating film, a hole which is in contact with at least a portion of the capacitor, the hole exposing the other one of the source/drain regions;
forming a third insulating film on inner side surfaces of the hole; and
forming, in the hole, a third contact connected to the other one of the source/drain regions.

10. A method according to claim 9, wherein the formation of the capacitor comprises:
etching the second electrode material and dielectric film; and
etching the first electrode material,
a size of the first electrode being larger than sizes of the second electrode material and dielectric film.

11. A method according to claim 9, wherein the formation of the hole comprises:
etching the second insulating film up to the second electrode; and
etching the second insulating film, second electrode, dielectric film, and first electrode.

12. A method according to claim 10, wherein the dielectric film is a ferroelectric film.

13. A semiconductor memory device fabrication method comprising:
forming a transistor having a gate electrode and source/drain regions in a surface region of a semiconductor substrate;
forming, on the semiconductor substrate, a first insulating film which covers the transistor;
forming, in the first insulating film, a first contact connected to one of the source/drain regions;
forming a first electrode material, dielectric film, and second electrode material sequentially on the first insulating film;
etching the second electrode material, dielectric film, and first electrode material to form a capacitor having a first electrode, dielectric film, and second electrode;
forming a second insulating film on a sidewall of the capacitor;
forming, on the first insulating film, a third insulating film which covers the capacitor;
forming, in the third insulating film, a second contact connected to the second electrode;
forming, in the first and third insulating films, a hole which is in contact with at least a portion of the capacitor, the hole exposing the other one of the source/drain regions; and
forming, in the hole, a third contact connected to the other one of the source/drain regions.

14. A method according to claim 13, wherein the dielectric film is a ferroelectric film.

15. A semiconductor memory device fabrication method comprising:
forming a transistor having a gate electrode and source/drain regions in a surface region of a semiconductor substrate;
forming, on the semiconductor substrate, a first insulating film which covers the transistor;
forming, in the first insulating film, a first contact connected to one of the source/drain regions;
forming a first electrode material, dielectric film, and second electrode material sequentially on the first insulating film;
etching the second electrode material, dielectric film, and first electrode material to form a capacitor having a first electrode, dielectric film, and second electrode;
forming, on the first insulating film, a second insulating film which covers the capacitor;
forming, in the second insulating film, a second contact connected to the second electrode;
forming, in the first and third insulating films, a hole which is in contact with a sidewall of the capacitor, the hole exposing the other one of the source/drain regions;
forming an insulating portion by oxidizing the sidewall of the capacitor from the hole; and
forming, in the hole, a third contact connected to the other one of the source/drain regions.

16. A method according to claim 15, wherein the dielectric film is a ferroelectric film.

17. A semiconductor memory device fabrication method comprising:
forming a transistor having a gate electrode and source/drain regions in a surface region of a semiconductor substrate;
forming, on the semiconductor substrate, a first insulating film which covers the transistor;
forming, in the first insulating film, a first contact connected to one of the source/drain regions;
forming a second insulating film on the first insulating film;
forming, in the first and second insulating films, a second contact connected to the other one of the source/drain regions;
forming a first electrode material, electric film, and second electrode material sequentially on the second insulating film;
etching the second electrode material, dielectric film, and first electrode material to form a capacitor having a first electrode, dielectric film, and second electrode;
forming, on the second insulating film, a third insulating film which covers the capacitor;
forming, in the third insulating film, a third contact connected to the second electrode;
forming, in the second and third insulating films, a hole which is in contact with a sidewall of the capacitor, the hole exposing the other one of the source/drain regions;
forming a fourth insulating film on side surfaces of the hole; and
forming, in the hole, a fourth contact connected to the first contact.

18. A method according to claim 17, wherein the dielectric film is a ferroelectric film.

19. A semiconductor memory device fabrication method comprising:
forming a transistor having a gate electrode and source/drain regions in a surface region of a semiconductor substrate;
forming, on the semiconductor substrate, a first insulating film which covers the transistor;
forming, in the first insulating film, a first contact connected to one of the source/drain regions, and a second contact connected to the other one of the source/drain regions;
forming a first electrode material, dielectric film, and second electrode material sequentially on the first insulating film;
etching the second electrode material, dielectric film, and first electrode material to form a capacitor having a first electrode connected to the first contact, a dielectric film, and a second electrode;
forming, on the first insulating film, a second insulating film which covers the capacitor;
forming, in the second insulating film, a third contact connected to the second electrode;
forming, in the second insulating film, a hole which is in contact with a sidewall of the capacitor, the hole exposing an upper surface of the second contact;
forming a third insulating film on side surfaces of the hole; and
forming, in the hole, a fourth contact connected to the second contact.

20. A method according to claim 19, wherein the dielectric film is a ferroelectric film.
